(19) United States
(12) Patent Application Publication
(10) Pub. No.: US 2007/0242505 A1
(43) Pub. Date: Oct. 18, 2007

(54) Magnetic memory device and method for driving the same

(75) Inventors: Takao Ochiai, Kawasaki (JP); Shinjiro Umehara, Kawasaki (JP); Hiroshi Ashida, Kawasaki (JP); Masashige Sato, Kawasaki (JP); Kazuo Kobayashi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/446,303

(22) Filed: Jun. 5, 2006

(30) Foreign Application Priority Data
Mar. 30, 2006 (JP) 2006-093446

(51) Int. Cl. G11C 11/14

(52) U.S. Cl. 365/171

(57) ABSTRACT

The magnetic memory device comprises a magnetoresistive effect element 54 including a magnetic layer 42 having a magnetization direction pinned in a first direction, a non-magnetic layer 50 formed on the magnetic layer 42, and a magnetic layer 52 formed on the non-magnetic layer 50 and having a first magnetic domain magnetized in a first direction and a second magnetic domain magnetized in a second direction opposite to the first direction; and a write current applying circuit for flowing a write current in the second magnetic layer 52 in the first direction or the second direction to shift a magnetic domain wall between the first magnetic domain and the second magnetic domain to control a magnetization direction of a part of the magnetic layer 52, opposed to the magnetic layer 42.

### CROSS-REFERENCE TO RELATED APPLICATIONS

This application is based upon and claims the benefit of priority from the prior Japanese Patent Application No. 2006-093446, filed on Mar. 30, 2006, the entire contents of which are incorporated herein by reference.

### BACKGROUND OF THE INVENTION

The present invention relates to a magnetic memory device and a method for driving the same, more specifically, a magnetic memory device using a spin injection-type magnetoresistive effect element and a method for deriving the magnetic memory device.

Recently, as a rewritable nonvolatile memory a magnetic random access memory (hereinafter called an MRAM) including magnetoresistive effect elements arranged in a matrix is noted. The MRAM uses combinations of magnetization directions of two magnetic layers to memorize information and, to read the information, detects resistance changes (i.e., current changes or voltage changes) between the resistance with the magnetization directions of the two magnetic layers being parallel with each other and the resistance with the magnetization directions of the two magnetic layers being anti-parallel with each other.

As the magnetoresistive effect element forming the MRAM are known the GMR (Giant Magnetoresistive) element and the TMR (Tunneling Magnetoresistive) element. Of them, the TMR element, which provides large resistance changes, is noted as the magnetoresistive effect element to be used in the MRAM. The TMR element includes two ferromagnetic layers laid one on another with a tunnel insulating film formed therebetween and utilizes the phenomena that the tunnel current which flows between the magnetic layers via the tunnel insulating film changes based on relationships of the magnetization directions of the two ferromagnetic layers. That is, the TMR element has low element resistance when the magnetization directions of the two ferromagnetic layers are parallel with each other and has high element resistance when both are anti-parallel with each other. These two states are related to data “0” and data “1” to use the TMR element as a memory device.

As the method for writing in the magnetoresistive effect element, the method (current magnetic field writing method) of flowing current in two signal lines (e.g., a bit line and a write word line) which normally intersect each other and applying a synthetic magnetic field of magnetic fields generated from the signal lines to the MTJ element to thereby change a magnetization direction of one of the ferromagnetic layer (free magnetization layer) corresponding to the applied magnetic field is generally used.

However, in this method, the electric power consumption and reliability depend on the generation efficiency of the synthetic magnetic field generated by the bit line and the write word line and the ease of inversion of the free magnetization layer to the external magnetic field. Especially, as the size of the magnetoresistive effect element is more diminished for higher memory density, the demagnetizing field of the free magnetization layer is increased, which increases the magnetization reversal magnetic field Hc of the free magnetization layer. That is, as the integration is higher, the write current is increased, and the electric power consumption is increased.

To solve this, the so-called clad structure, in which the surroundings of the bit line and the write word line except the surfaces opposed to the magnetoresistive effect element are shielded to concentrate the magnetic fluxes, is proposed. However, the magnetization reversal magnetic field of the free magnetization layer is increased in inverse proportion with the decrease of the size, and the conventional current magnetic writing method drastically increases the write current, which will really make the write difficult.

In writing data, current is applied to the bit line and the write word line to inverse the magnetization of the free magnetization layer of prescribed selected element by the synthetic magnetic fields. At this time, the current magnetic fields act on a number of non-selected elements connected to the bit line and the write word line the current was applied to. The elements in such state are defined as to be in half-selected state; the magnetization reversal tends to unstably take place, which is a cause for erroneous operations. In the MRAM with the select transistor connected to, the write word line for writing is necessary in addition to the bit lines and the word lines, which complicates the device structure and the fabrication process.

In view of this, recently, the spin injection magnetization reversal element is noted. The spin injection magnetization reversal element is a magnetoresistive effect element including two magnetic layers with an insulating film or a non-magnetic metal layer formed therebetween, as do the GMR element and the TMR element.

In the spin injection magnetization reversal element, when current is flowed from the free magnetization layer to the pinned magnetization layer perpendicularly to the film surface, the spin polarized conduction electrons flow from the pinned magnetization layer to the free magnetization layer to make the exchange interaction with the electrons in the free magnetization layer, Resultantly, torques are generated between the electrons, and when the torques are sufficiently large, the magnetic moment of the free magnetization layer is inverted from anti-parallel to parallel. On the other hand, when the current is oppositely applied, the effect of the action opposite to the above can inverse the magnetic moment from parallel to anti-parallel. That is, the spin injection magnetization reversal element is a memory element which can induce the magnetization reversal of the free magnetization layer by the current control alone to rewrite a memory state.

The spin injection magnetization reversal element, in which even when the element size is decreased, and the magnetization reversal magnetic field Hc is increased, the inversion current is decreased due to the effect of the decreased volume, is very advantageous to increase the capacity and decrease the electric power consumption in comparison with the current magnetic field writing element. Furthermore, no write word lines are necessary, which allows the device structure and the fabrication method to be simplified.

Related arts are disclosed in, e.g., Reference 1 (Japanese published unexamined patent application No. 2000-195250), Reference 2 (Japanese published unexamined patent application No. 2002-299584), Reference 3 (T. Miyazaki et al., “Giant magnetic tunneling effect in Fe/Al₂O₃/Fe junction”, J. Magn. Magn. Mater., 139, p.L231 (1995)), Reference 4 (K. Yagami et al., “Study trend of spin-injection magnetization reversal”, journal of the magnetic society for Japan, Vol. 28 No.9, 2004, pp.937-948), Reference 5 (J. A. Katine et al. “Current-driven magnetization reversal and spin-wave excitation in Co/Cu/Co pillars”, Phys. Rev. Lett., 84, p.3149 (2000)), Reference 6 (L. Berger, “Motion of a magnetic domain wall traversed by fast-rising current pulses”, J. Appl. Phys., 71, p.2721 (1992)), and Reference 7 (A. Yamaguchi et al., “Real-space observation of current-driven domain wall motion in submicron magnetic wires”, Phys. Rev. Lett., 92, p.077205-1 (2004)).

However, in the spin injection magnetization reversal element in which current is flowed perpendicularly to the film surface, large current must be flowed repeatedly for every writing. Accordingly, dielectric breakdown and pin holes are often generated in the barrier layer, and the interconnections are often broken by the electromigration. This is a cause for degrading the reliability of devices.

Generally, the TMR element has very high resistance of the element itself, and for the spin injection writing, the barrier layer must have a not more than 1 nm thickness. However, making the barrier film thin much decreases intrinsically the MR ratio (change ratio of the electric resistance between the magnetization parallel state and anti-parallel state), and the S/N ratio, which is practically important to devices is decreased.

### SUMMARY OF THE INVENTION

An object of the present invention is to provide a magnetic memory device which can improve the reliability of the barrier layer and the S/N ratio of the output, and a method for driving the magnetic memory device.

According to one aspect of the present invention, there is provided a magnetic memory device comprising: a magnetoresistive effect element including: a first magnetic layer having a magnetization pinned in a first direction; a non-magnetic layer formed on the first magnetic layer; and a second magnetic layer formed on the non-magnetic layer, and having a first magnetic domain magnetized in the first direction and a second magnetic domain positioned adjacent to the first magnetic domain in the first direction and magnetized in a second direction opposite to the first direction; and a write current applying circuit for flowing a write current to the second magnetic layer in the first direction or the second direction to shift a magnetic domain wall between the first magnetic domain and the second magnetic domain and control a magnetization direction of a part of the second magnetic layer, opposed to the first magnetic layer.

According to another aspect to the present invention, there is provided a method for driving a magnetic memory device for driving a magnetic memory device including a magnetoresistive effect element including: a first magnetic layer having a magnetization pinned in a first direction; a non-magnetic layer formed on the first magnetic layer; and a second magnetic layer formed on the non-magnetic layer, and having a first magnetic domain magnetized in the first direction and a second magnetic domain positioned adjacent to the first magnetic domain in the first direction and magnetized in a second direction opposite to the first direction, a write current of the first direction or the second direction is flowed in the second magnetic layer to shift a magnetic domain wall between the first magnetic domain and the second magnetic domain and control a magnetization direction of a part of the second magnetic layer, opposed to the first magnetic layer.

According to the present invention, the magnetoresistive effect element comprises a first magnetization layer having the magnetization direction pinned in a first direction, a non-magnetic layer formed on the first magnetic layer, and a second magnetic layer having a first magnetic domain magnetized in the first direction and a second magnetic domain positioned adjacent to the first magnetic domain in the first direction and magnetized in a second direction opposite to the first direction. Memory information of the magnetoresistive effect element is rewritten by flowing in-plane write current in the second magnetic layer to shift the magnetic domain wall between the first magnetic domain and the second magnetic domain to control the magnetization direction in a part of the second magnetic layer, opposed to the first magnetic layer. It is not necessary to flow the write current in the non-magnetic layer. This prevents the degradation of the non-magnetic layer and lasts the magnetic memory device. Resultantly, this can increase the reliability.

The write current is not flowed via the non-magnetic layer, which permits the non-magnetic layer to be thicker in comparison with that of the conventional spin injection magnetization reversal type magnetoresistive effect element. This can increase the MR ratio of the magnetoresistive effect element and improve the S/N ratio of the output.

### BRIEF DESCRIPTION OF THE DRAWINGS

FIG. 1 is a plan view of the magnetic memory device according to one embodiment of the present invention.

FIGS. 2A and 2B are diagrammatic sectional views of the magnetic memory device according to the embodiment of the present invention.

FIGS. 3A-3C are plan views showing the operational principle of the magnetic memory device according to the embodiment of the present invention.

FIGS. 4A and 4B are sectional views showing the operational principle of the magnetic memory device according to the embodiment of the present invention.

FIG. 5 is a graph of the barrier layer film thickness dependency of the MR ratio of the magnetoresistive effect element.

FIGS. 6A-6C, 7A-7B, 8A-8B, 9A-9C, 10A-10B and 11A-11B are sectional views of the magnetic memory device according to the embodiment of the present invention in the steps of the method for fabricating the same.

### DETAILED DESCRIPTION OF THE INVENTION

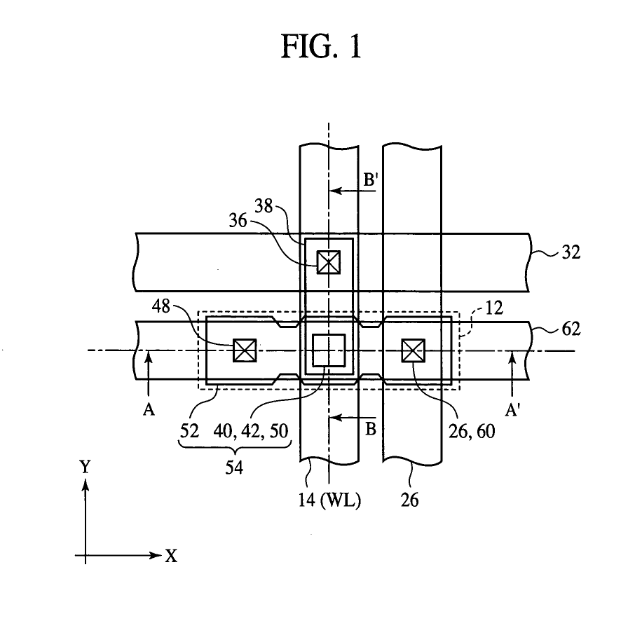

The magnetic memory device and the method for driving the same according to one embodiment of the present invention will be explained with reference to FIGS. 1 to 11B.

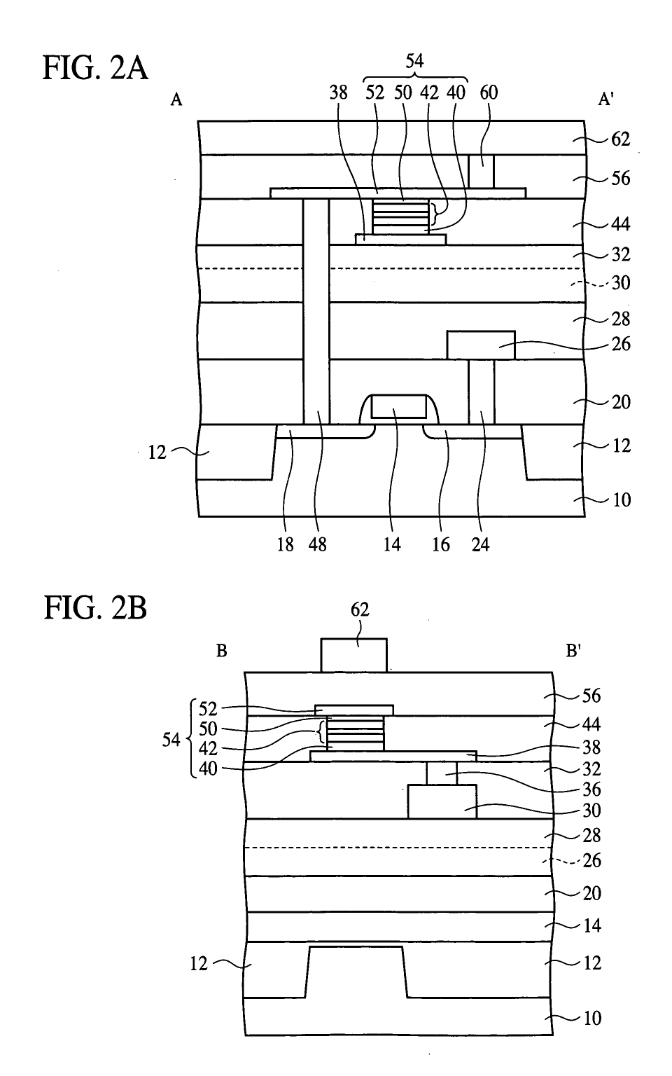

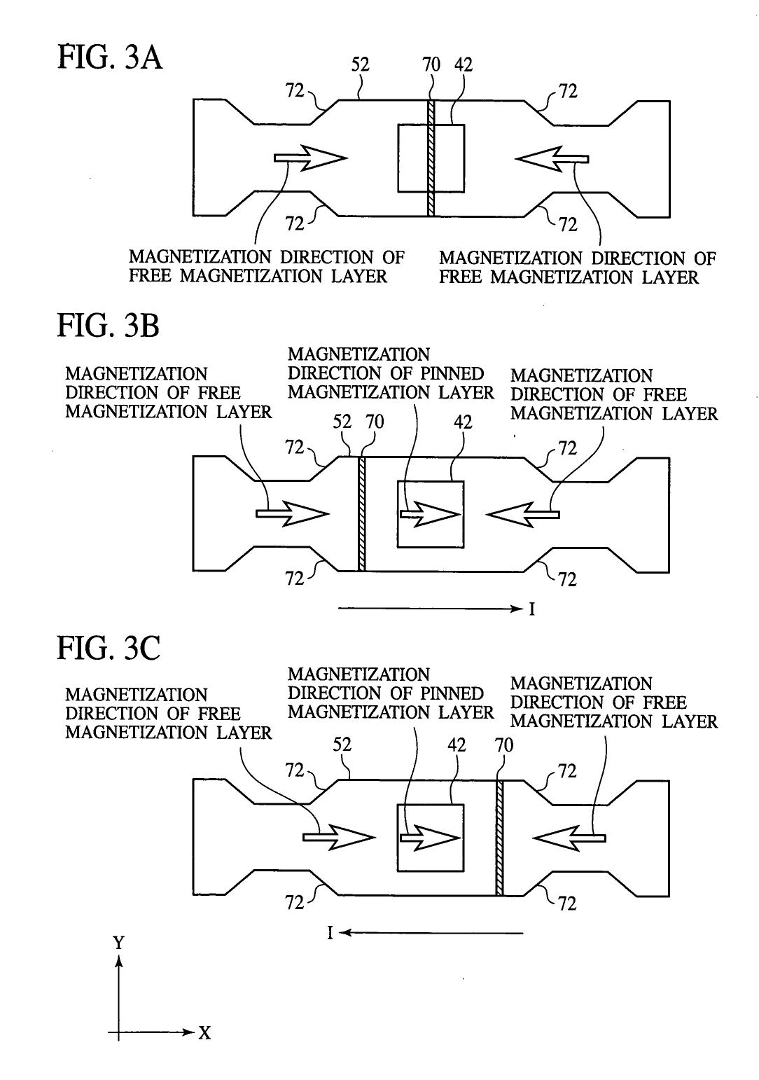

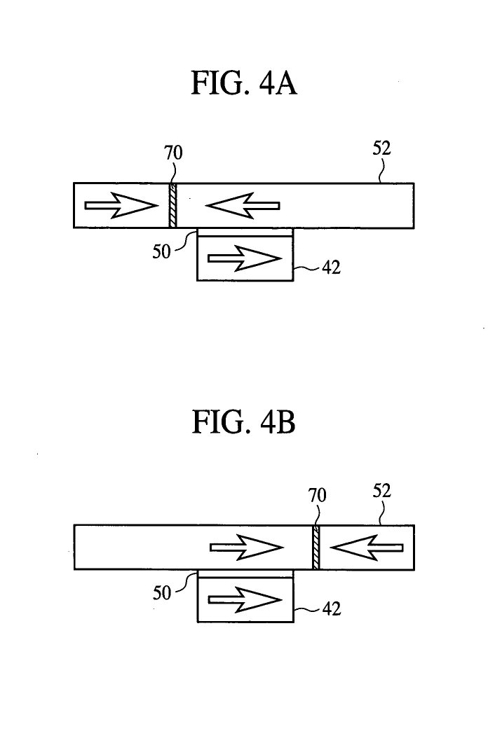

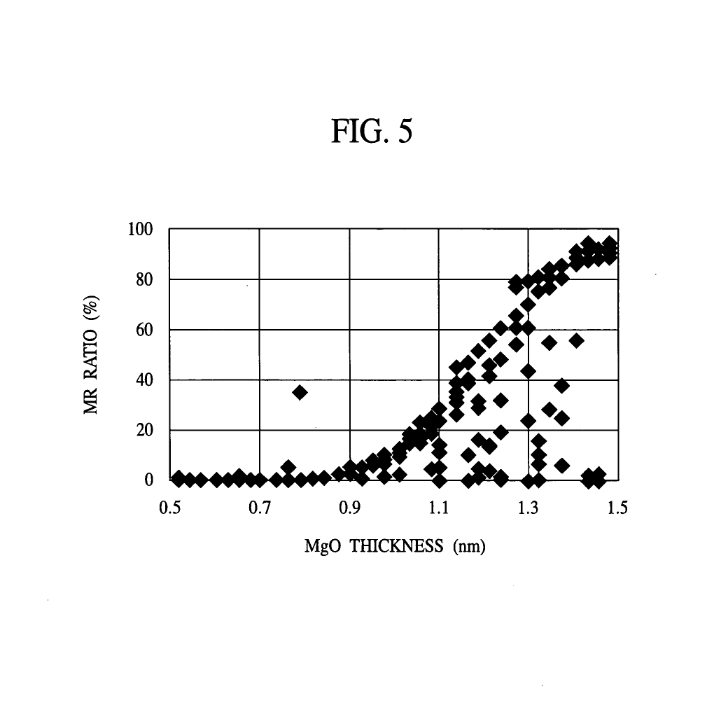

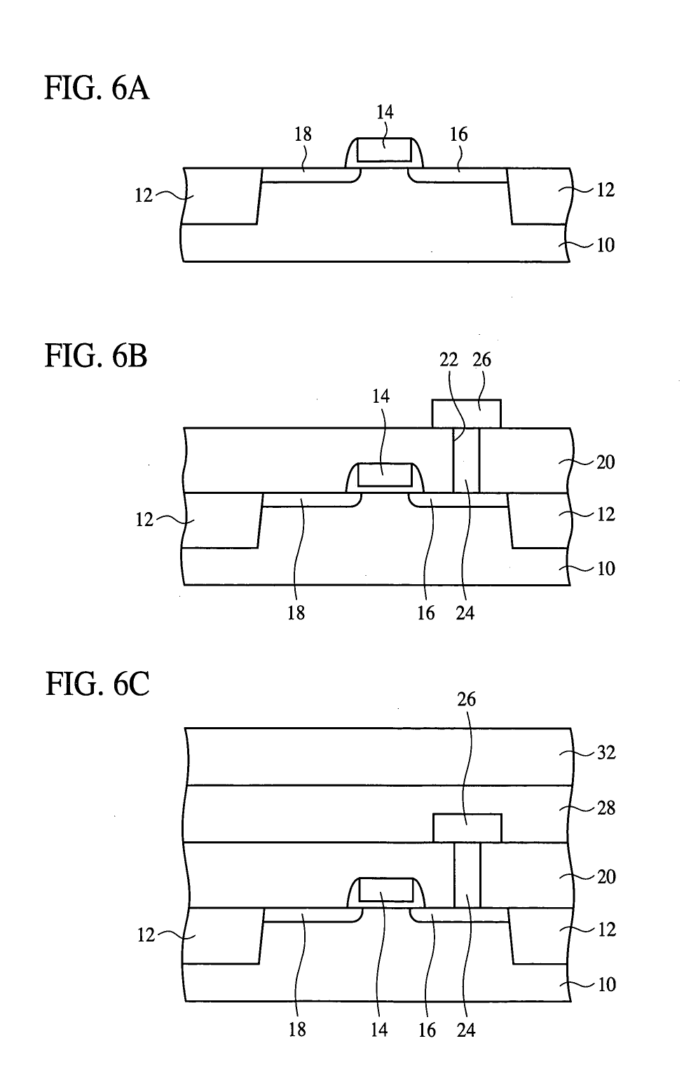

FIG. 1 is a plan view of the magnetic memory device according to the present embodiment, which shows a structure thereof. FIGS. 2A and 2B are diagrammatic sectional views of the magnetic memory device according to the present embodiment, which show the structure thereof. FIGS. 3A-3C are plan views showing the operational principle of the magnetic memory device according to the present embodiment. FIGS. 4A and 4B are sectional views showing the operational principle of the magnetic memory device according to the embodiment of the present invention. FIG. 5 is a graph of the barrier layer film thickness dependency of the MR ratio of the magnetoresistive effect element. FIGS. 6A to 11B are sectional device of the magnetic memory device according to the present embodiment in the steps of the method for fabricating the same, which show the method.

First, the structure of the magnetic memory device according to the present embodiment will be explained with reference to FIGS. 1 and 2A-2B. FIG. 2A is the sectional view along the line A-A′ in FIG. 1. FIG. 2B is the sectional view along the line B-B′ in FIG. 1.

A device isolation film 12 for defining a device region is formed on a silicon substrate 10. The device region has a rectangular shape elongated in the X-direction.

On the silicon substrate 10 with the device isolation film 12 formed on, a word line WL is formed, extended in the Y-direction. In the device region on both sides of the word line WL, source/drain regions 16, 18 are formed. Thus, in the device region, a select transistor comprising the gate electrode 14 formed of the word line WL and the source/drain regions 16, 18 is formed.

On the silicon substrate 10 with the select transistor formed on, an inter-layer insulating film 20 is formed. In the inter-layer insulating film 20, a contact plug 24 connected to the source/drain region 16 is formed. On the inter-layer insulating film 20 with the contact plug 24 formed in, a source line 26 is formed, extended in the Y-direction and electrically connected to the source/drain region 16 via the contact plug 24.

On the inter-layer insulating film 20 with the source line 26 formed on, an inter-layer insulating film 28 is formed. On the inter-layer insulating film 28, a read bit line 30 is formed, extended in the X-direction.

On the inter-layer insulating film 28 with the read bit line 30 formed on, an inter-layer insulating film 32 is formed. In the inter-layer insulating film 32, a contact plug 36 connected to the read bit line 30 is formed. On the inter-layer insulating film 32 with the contact plug 36 formed in, a lower electrode layer 30 is formed, electrically connected to the read bit line 30 via the contact plug 36.

On the lower electrode layer 38, an anti-ferromagnetic layer 40, a pinned magnetization layer (a first magnetic layer) 42 and a barrier layer (a non-magnetic layer) 50 are formed. On the inter-layer insulating film 32 with the lower electrode layer 38, the anti-ferromagnetic layer 40 and the pinned magnetization layer 42 and the barrier layer 50 formed on, an inter-layer insulating film 44 is formed, burying the lower electrode layer 38, the anti-ferromagnetic layer 40 and the pinned magnetization layer 42 and the barrier layer 50 with the upper surface of the barrier layer 50 exposed. In the inter-layer insulating films 44, 32, 28, 20, a contact plug 48 connected to the source/drain region 18 is formed.

On the inter-layer insulating film 44, a free magnetization layer (a second magnetic layer) 52 is formed electrically connected to the source/drain region 18 via the contact plug 48 and opposed to the pinned magnetization layer 42 with the barrier layer 50 formed therebetween. Thus, a magnetoresistive effect element 54 comprising the anti-ferromagnetic layer 40, the pinned magnetization layer 42, the barrier layer 50 and the free magnetization layer 52 is formed. The magnetoresistive effect element 54 has the free magnetization layer 52 extended in the X-direction and the pinned magnetization layer 42 arranged at the center with the barrier layer 50 formed therebetween.

On the inter-layer insulating film 44 with the free magnetization layer 52 formed on, an inter-layer insulating film 56 is formed. In the inter-layer insulating film 56, a contact plug 60 connected to the free magnetization layer 52 is formed. On the inter-layer insulating film 56 with the contact plug 60 formed in, a write bit line 62 is formed, extended in the X-direction and electrically connected to the free magnetization layer 52 via the contact plug 60.

Thus, the spin injection magnetic memory device including a memory cell formed of one select transistor and one magnetoresistive effect element is formed.

In the magnetic memory device according to the present embodiment, as described above, the free magnetization layer 52 of the magnetoresistive effect element 54 is elongated in the X-direction, and write current can be flowed in plane along the direction of the length of the free magnetization direction 52. The pinned magnetization layer 42 is provided on the central part of the fee magnetization layer 52 of the magnetoresistive effect element 54 with the barrier layer 50 formed therebetween, so that read current can be flowed perpendicularly to plane.

Next, the operational principle of the magnetoresistive effect element 54 of the magnetic memory device according to the present embodiment will be explained with reference to FIGS. 3A and 4B.

As shown in FIG. 3A, the free magnetization layer 52 is elongated in the X-direction. Trapezoidal notches 72 are formed in the free magnetization layer 52 respectively near both ends thereof to decrease the width of the free magnetization layer 52. At the center of the free magnetization layer 52, the pinned magnetization layer 42 is formed with the barrier layer (not shown) therebetween.

It is assumed here that the magnetization directions of the magnetic domains of the free magnetization layer 52 are opposed to each other with respect to the magnetic domain wall 70. That is, in FIG. 3A, the magnetization direction on the right side of the free magnetization layer 52 is left, and on the left side of the magnetization layer 52, the magnetization direction is right. It is assumed that the magnetization direction of the pinned-magnetization layer 42 is right in FIG. 3A. The magnetization directions of the magnetic domains are opposite to each other with respect to the magnetic domain wall is a general property of the ferromagnetic material.

In the state shown in FIG. 3A, when current is flowed in plane of the free magnetization layer in the direction of the length of the free magnetization layer 52, the magnetic domain wall 70 is shifted in the direction of the electron spins. For example, in FIG. 3A, when current I is flowed to the right, the electron spins are directed left, and the magnetic domain wall 70 is shifted left (FIG. 3B). In FIG. 3A, when current I is flowed to the left, the electron spins are directed right, and the magnetic domain wall 70 is shifted right (FIG. 3C).

At this time, the magnetic domain wall 70 is shifted left or right beyond the region where the pinned magnetization wall 42 is formed, a magnetization direction of a part of the free magnetization layer 52, opposed to the pinned magnetization layer 42 with the barrier layer 50 therebetween is changed.

That is, as shown in FIGS. 4A-4B, when the magnetic domain wall 70 is shifted left beyond the pinned magnetization layer 42, the magnetization direction of the part of the free magnetization layer 52, opposed to the pinned magnetization layer 42 is left, and the magnetization direction of the pinned magnetization layer 42 and the magnetization direction of the free magnetization layer 52 are anti-parallel (high resistance state) with each other (FIG. 4A). Oppositely, when the magnetic domain wall 70 is shifted right beyond the pinned magnetization layer 42, the magnetization direction of the part of the free magnetization layer 52, opposed to the pinned magnetization layer 42 is right, and the magnetization direction of the pinned magnetization layer 42 and the magnetization direction of the free magnetization layer 52 are parallel (low resistance state) with each other (FIG. 4B).

Thus, the shift of the magnetic domain wall by the electron spin injection is utilized to define two-valued states that the magnetization directions of the magnetoresistive effect element are parallel and anti-parallel.

However, in the free magnetization layer 52 simply formed in a fine line structure, the magnetic domain wall 70 continues to be shifted in the direction of the electron spins. To prevent this, the notches 72 are provided in the free magnetization layer 52 near both ends thereof. It is generally known that the thin line structure has a defect, such as a crack or a cut, the shift of the magnetic domain wall is pinned there. Then, the notches 72 called the magnetic domain wall pinning sites are provided in the free magnetization layer 52 near both ends, whereby the range of the shift of the magnetic domain wall 70 can be controlled, and the operational reliability of the writing can be improved.

The notches 72 are not essentially trapezoidal as shown and can provide the same effect in a wedge-shape, rectangular shape, semi-spherical shape or other shapes. The shape of the notches 72 can be freely selected corresponding to a device structure.

In the single ferromagnetic fine line, in which the magnetization is directed in the direction of the length of the fine line, and both ends of the fine line are magnetic poles, it is generally difficult that the magnetic domain wall takes place. However, when the fine line has irregular patterns, the magnetic domain walls tend to take place at the parts. For example, it has been confirmed that a 500 nm-rhombic pattern is formed at the end of a 240 nm-width fine line, and an external magnetic field is applied at 26 degrees to the extension of the fine line, whereby the magnetic domain wall can be induced in the fine line having no magnetic domain wall (e.g., see Reference 7). In the present embodiment as well, it is possible that such method is utilized to induce the magnetic domain wall in the free magnetization layer 52.

Then, the method for writing the magnetic memory device according to the present embodiment will be explained.

For the writing in the magnetic memory device shown in FIGS. 2A and 2B, the write bit line 62, the source line 26 and the word line WL (gate electrode 14) are used, and the read bit line 30 floats.

When a prescribed drive voltage is applied to the word line WL, and the select transistor is turned on, a current path of the write bit line 62—the contact plug 60—the free magnetization layer 52—the contact plug 48—the select transistor—the source line 26 serially connected to each other is formed between the write bit line 62 and he source line 26. In this current path, the prescribed write current can be flowed in the in-plane direction of the free magnetization layer 52. Accordingly, the direction of the current flowed in the current path is suitably changed to thereby memory required information in the magnetoresistive effect element 54.

For example, the write current is flowed from the source line 26 toward the write bit line 62, whereby in the free magnetization layer 52, the magnetic domain wall 70 is shifted in the direction shown in FIG. 3B, and the magnetoresistive effect element has the high resistance state. The write current is flowed from the write bit line 62 toward the source line 26, whereby in the free magnetization layer 52, the magnetic domain wall 70 is shifted in the direction shown in FIG. 3C, and the magnetoresistive effect element has the low resistance state.

In the writing of the magnetoresistive effect element 54 utilizing the shift of the magnetic domain wall by the electron spin injection as described above, it is not necessary to flow the write current perpendicularly to plane, i.e., via the barrier layer 50. Accordingly, the barrier layer 50 is free from the degradation due to the writing, and the reliability, such as the device life, etc., can be improved.

In the magnetic memory device including a plurality of the magnetoresistive effect elements 54, when bit information of the magnetoresistive effect elements 54 is initialized at once, it is effective to apply a strong external magnetic field in one direction.

Then, the method for reading the magnetic memory device according to the present embodiment will be explained.

In the reading of the magnetic memory device shown in FIGS. 2A and 2B, the read bit line 30, the source line 26 and the word line WL (gate electrode 14) are used, and the write bit line 62 floats.

When a prescribed drive voltage is applied to the word line WL, and the select transistor is turned on, the current path of the read bit line 30—the contact plug 36 the magnetoresistive effect element 54—the contact plug 48—the selection-transistor—the source line 26 serially connected to each other is formed between the read bit line 30 and the source line 26. In this current path, the read current can be flowed to the magnetoresistive effect element 54 perpendicularly to plane. Accordingly, the read current is flowed by this current path, and a voltage outputted to the read bit line 30 is detected, whereby the resistance state of the magnetoresistive effect element 54 can be judged.

Next, characteristics of the magnetic memory device according to the present embodiment will be proved.

First, the electric power consumption of the magnetoresistive effect element will be discussed.

When a real resistance (except the parasitic resistances of the circuit, etc.) of the magnetoresistive effect element R_{TMR} is 5 kΩ, a device area S is 0.01 μm², and a write voltage Vw is 500 mV, a write current Iw for the conventional MRAM, in which the write current is flowed perpendicularly to plane (hereinafter called CPP (Current Perpendicular to Plane) type MRAM), is

I_{W}=V_{W}/R_{TMR}=0.1 mA

### Accordingly, an electric power consumption W for the writing is

W=V_{W}×I_{W}=500 mV×0.1 mA=50 μW

On the other hand, in the MRAM, in which the write current is flowed in the in-plane direction of the free magnetization layer according to the present embodiment (hereinafter called a CIP (Current in In-Plane) type MRAM), when a sectional area S of the free magnetization layer 52 of NiFe is 240 nm×100 nm, a write current Iw is Iw=Jc×S=3.12 mA, a specific resistance ρ_{Fe} of Fe is ρ_{Fe}=1.0×10⁻⁷ Ω-cm, and a shift distance L of the magnetic domain wall is 1.5 μm, a real resistance R of the free magnetization layer is

$$\begin{matrix}R = {ρ}_{Fe} \times L / S \\ = 1.0 \times {10}^{- 7} Ω \text{-} cm \times 1.5 μm / ( 240 nm \times 10 nm ) \\ = 0.628 Ω .\end{matrix}$$

### Accordingly, an electric power consumption W required to shift the magnetic domain wall by 1.5 μm is

W=I²×R(3.12 mA)²×0.628 Ω=6.1 μW

It is found that the present embodiment can decrease the electric power consumption by one place in comparison with that of the CPP-type MRAM. This is due to the fact that the tunnel resistance of the barrier layer is very high in the CPP-type MRAM, but in the CIP-type MRAM, wherein the electric conduction is in the metal, the resistance is very low.

Then, the output of the magnetoresistive effect element will be discussed.

FIG. 5 is a graph of the barrier layer thickness dependency of the MR ratio of the magnetoresistive effect element using MgO as the barrier layer. The MR ratio is the change ratio of the electric resistance between the parallel magnetization directions and the anti-parallel magnetization directions of the pinned magnetization layer and the free magnetization layer of the magnetoresistive effect element. As the MR ratio is higher, the read margin is larger, which indicates the improved S/N ratio.

As shown, it is found that when the MgO film thickness is about 1.5 nm, the MR ratio can be approximately 100%. However, when the MgO film thickness is decreased down to 0.9 nm, the MR ratio is decreased to not more than 10%.

In the conventional CPP-type MRAM, the element resistance of the magnetoresistive effect element itself is high because of the presence of the barrier layer, and to decrease the electric power consumption for the writing, the barrier layer must be thinned, sacrificing the output characteristics. On the other hand, in the CIP-type MRAM according to the present embodiment, the presence of the barrier layer is irrelevant to the electric power consumption for the writing, and taking into consideration only the applied voltage for the reading, the magnetoresistive effect element can be designed, forming the barrier layer of a film thickness for the high output. The S/N ratio can be much improved in comparison with that of the CPP-type MRAM.

Next, the write speed of the magnetoresistive effect element will be discussed.

In the CIP-type MRAM according to the present embodiment, when a sectional area of the free magnetization layer 52 is S=240 nm×10 nm, and a write current Iw is Iw=Jc×S=3.12 mA, the magnetic domain wall was shifted by about 1.5 μm when a 0.5 msec write current pulse was applied. The average speed of the magnetic domain wall evaluated based on this result is 3 m/sec.

When it is assumed that a length of the memory part of the free magnetization layer 52 of the magnetoresistive effect element is 200 nm, a time required to shift the magnetic domain wall by this distance is 67 nsec. Considering that the write speed of the flash memory is in the μsec order, the write speed of the CIP-type MRAM according to the present embodiment is practically sufficiently high.

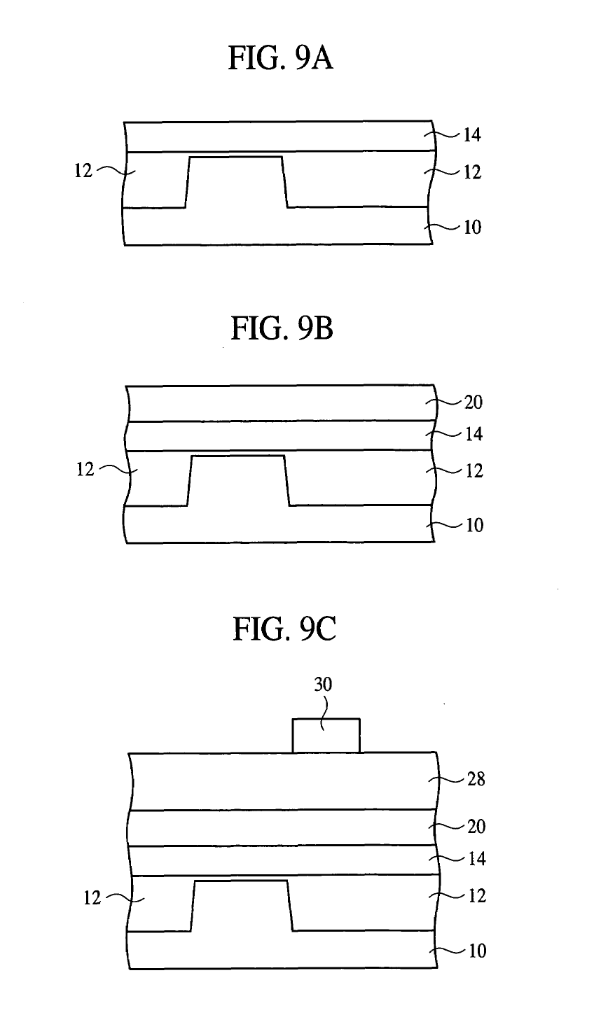

Then, the method for fabricating the magnetic memory device according to the present embodiment will be explained with reference to FIGS. 6A to 11B. FIGS. 6A to 8B are sectional views of the magnetic memory device along the line A-A′ of FIG. 1 in the steps of the method for fabricating the same, and FIGS. 9A to 11B are sectional views of the magnetic memory device along the line B-B′ of FIG. 1 in the steps of the method for fabricating the same.

First, the device isolation film 12 for defining a device region is formed on a silicon substrate 10 by, e.g., STI (Shallow Trench Isolation) method.

Then, in the device region defined by the device isolation film 12, a select transistor including the gate electrode 14 and the source/drain regions 16, 18 is formed in the same way as the usual MOS transistor fabricating method (FIGS. 6A and 9A).

Next, a silicon oxide film is deposited by, e.g., CVD method, on the silicon substrate 10 with the select transistor formed on, and the surface thereof is planarized by CMP method to form the inter-layer insulating film 20 of the silicon oxide film.

Next, by photolithography and dry etching, a contact hole is formed in the inter-layer insulating film 20 down to the source/drain region 16.

Next, a titanium nitride film as the barrier metal and a tungsten film are deposited by, e.g., CVD method, and these conductive films are etched back or polished back to form the contact plug 24 buried in the contact hole 22 and electrically connected to the source/drain region 16.

Next, a conductive film is deposited on the inter-layer insulating film 20 with the contact plug 24 buried in and patterned to form a source line 26 electrically connected to the source/drain region 16 via the contact plug 24 (FIGS. 6B and 9B).

Then, a silicon oxide film is deposited by, e.g., CVD method, on the inter-layer insulating film 20 with the source line 26 formed on, and the surface thereof is planarized by CMP method to form the inter-layer insulating film 28 of the silicon oxide film.

Next, a conductive film is deposited on the inter-layer insulating film 28 and patterned to from the read bit line 30 (FIG. 9C).

Then, on the inter-layer insulating film 28 with the read bit line 30 formed on, a silicon oxide film is deposited by, e.g., CVD method, and the surface thereof is planarized by CMP method to form the inter-layer insulating film 32 of the silicon oxide film.

Then, a contact hole 34 is formed in the inter-layer insulating film 32 down to the read bit line 30.

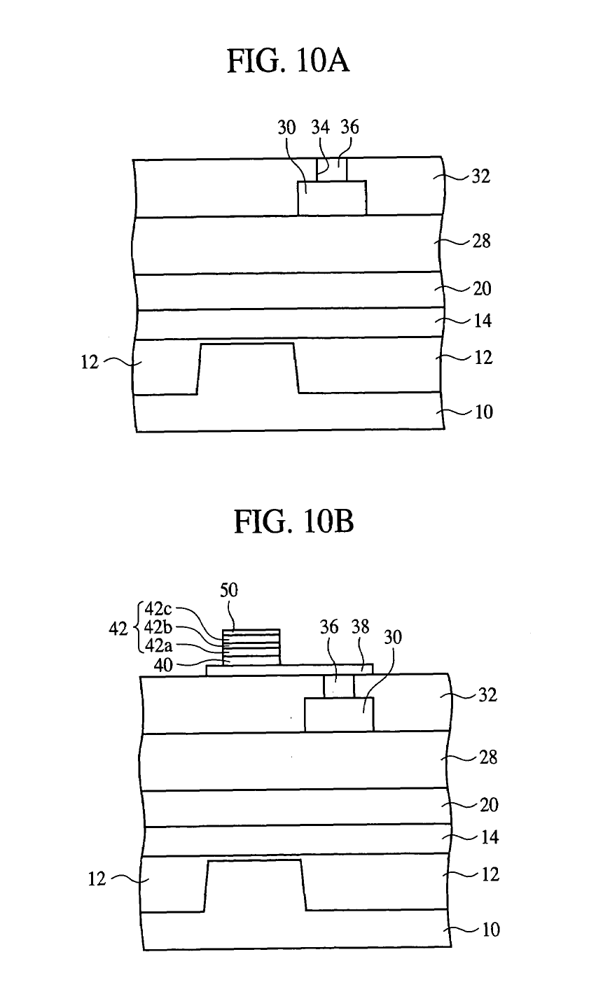

Then, a titanium nitride film as the barrier metal and a tungsten film are deposited, and these conductive films are etched back or polished back to form the contact plug 36 buried in the contact hole 34 and electrically connected to the read bit line 30 (FIGS. 6C and 10A).

Next, on the inter-layer insulating film 32 with the contact plug, 36 buried in, a Ta film, a PtMn film, a CoFe film, an Ru film, a CoFeB film and an MgO film are sequentially deposited on the inter-layer insulating film 32 with the contact plug 36 buried in.

Next, the MgO film, the CoFeB film, the Ru film, the CoFe film and the PtMn film are patterned to form the anti-ferromagnetic layer 40 of the PtMn film formed on the Ta film, the pinned magnetization layer 42 formed on the anti-ferromagnetic layer 40 and formed of the synthetic ferrimagnetic structure of the layer film of the CoFeB film 42c/the Ru film 42b/the CoFe film 42a, and the barrier layer 50 of the MgO film formed on the pinned magnetization layer 42.

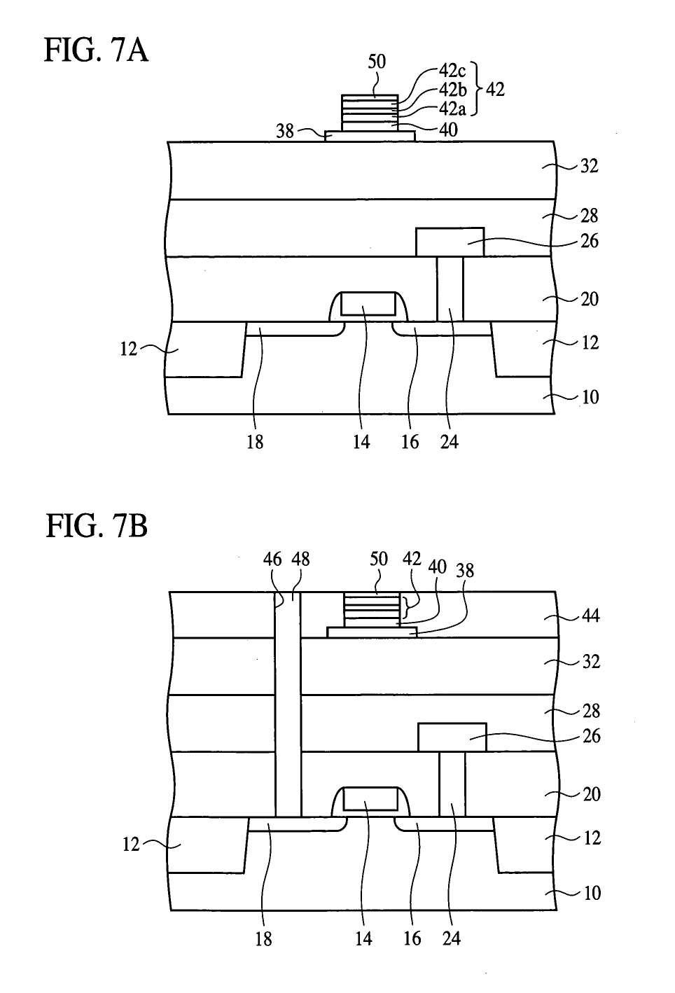

Then, the Ta film is patterned by photolithography and dry etching to form the lower electrode layer 38 of the Ta film (FIGS. 7A and 10B).

Next, on the inter-layer insulating film 32 with the lower electrode layer 38, the anti-ferromagnetic layer 40, the pinned magnetization layer 42 and the barrier layer 50 formed on, a silicon oxide film is deposited by, e.g., CVD method, and the surface thereof is polished by CMP method until the barrier layer 50 is exposed to form the inter-layer insulating film 44 of the silicon oxide film.

Next, by photolithography and dry etching, the contact hole 46 is formed in the inter-layer insulating film 44 down to the source/drain region 18.

Next, a titanium nitride film as the barrier metal and a tungsten film are deposited by, e.g., CVD method, and these conductive films are etched back or polished back to form the contact plug 48 buried in the contact hole 46 and electrically connected to the source/drain region 18 (FIG. 7B).

Next, on the inter-layer insulating film 44 with the contact plug 48 buried in, an NiFe film is deposited by, e.g., sputtering method.

Next, the NiFe film is patterned by photolithography and dry etching to form the free magnetization layer 52 of the NiFe film on the barrier layer 50.

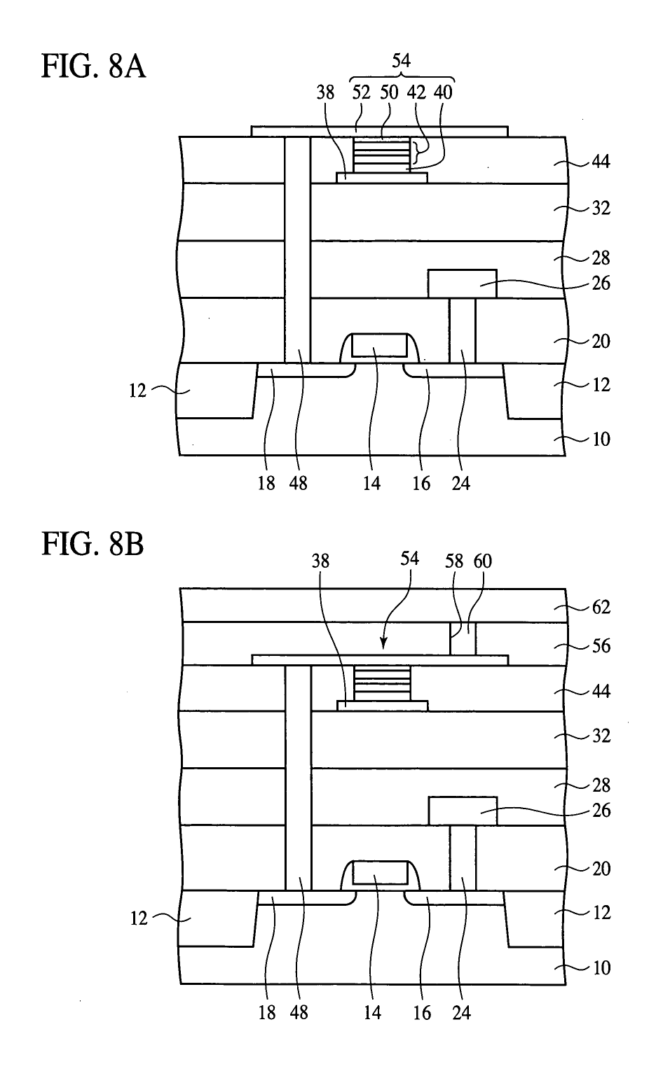

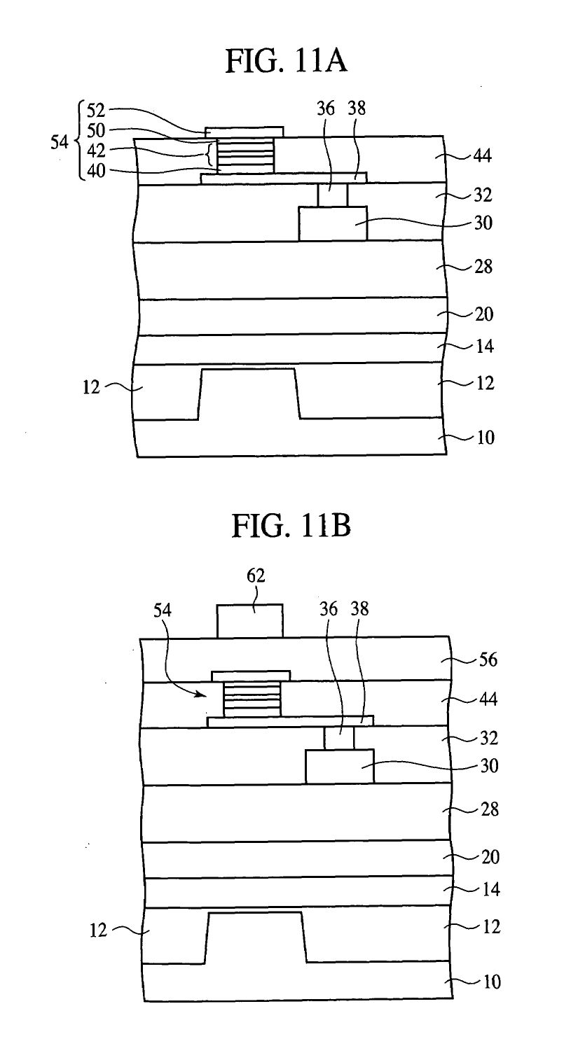

Thus, the magnetoresistive effect element 54 of the TMR structure including the anti-ferromagnetic layer 40, the pinned magnetization layer 42, the barrier layer 50 and the free magnetization layer 52 is formed (FIGS. 8A and 11A).

The anti-ferromagnetic layer 40 may be formed of, e.g., an anti-ferromagnetic material containing one of Re, Ru, Rh, Pd, IrPt, Cr, Fe, Ni, Cu, Ag and Au, and Mn, e.g., PtMn, PdPtMn, IrMn, RhMn, RuMn, FeMn or others.

The pinned magnetization layer 42 may be formed of a ferromagnetic material containing one of Co, Fe and Ni, e.g., CoFe, NiFe or others. With the synthetic ferrimagnetic structure formed, a non-magnetic material, such as Ru, Rh, Cr or others, may be used as the coupling film.

The barrier layer 50 may be formed of an oxide material, oxynitride material and nitride material containing one of Mg, Al, Hf, Ti, V, Ta, and Si, e.g., MgO, AlO, AlN, HfO, TiO, VO, TaO, SiO or others.

The free magnetization layer 52 may be formed of a ferromagnetic material containing one of Co, Fe and Ni, e.g., CoFeB, CoFeNi, CoFeSi, CoFeBSi, FeB, CoFe, NiFe or others.

On the inter-layer insulating film 44 with the magnetoresistive effect element 54 formed in, a silicon oxide film is deposited by, e.g., CVD method, and then the surface thereof is planarized by CMP method to form the inter-layer insulating film 56 of the silicon oxide film.

Then, by photolithography and dry etching, the contact hole 58 is formed in the inter-layer insulating film 56 down to the magnetoresistive effect element 54.

Then, a titanium nitride film as the barrier metal and a tungsten film are deposited by, e.g., CVD method, and these conductive films are etched back or polished back to form the contact plug 60 buried in the contact hole 58 and electrically connected to the read bit line 30.

Next, on the inter-layer insulating film 56 with the contact plug 60 buried in, a conductive film is deposited and patterned to form the write bit line 62 (FIGS. 8B and 11B).

Then, insulating layers, interconnection layers, etc. are formed thereon as required, and the magnetic memory device is completed.

As described above, according to the present embodiment, in the magnetoresistive effect element comprising the pinned magnetization layer having the magnetization pinned in a first direction, the barrier layer formed on the pinned magnetization layer, and the free magnetization layer on the barrier layer and having a first magnetic domain magnetized in the first direction and a second magnetic domain magnetized in a second direction opposite to the first direction, memory information is written in the magnetoresistive effect element by flowing write current in the free magnetization layer in the in-plane direction to thereby shift the magnetic domain wall between the first magnetic domain and the second magnetic domain to thereby control a magnetization direction of a part of the free magnetization layer, opposed to the pinned magnetization layer, whereby it is not necessary that the write current is flowed via the barrier layer. This prevents the degradation of the barrier layer and allows the barrier layer to last long. Resultantly, the reliability of the magnetic memory device can be improved.

The write current is not flowed via the barrier layer, which allows the barrier layer to be thicker in comparison with that of the conventional spin injection magnetization reversal type magnetoresistive effect element, whereby the MR ratio of the magnetoresistive effect element is increased, and the S/N ratio of the output can be improved.

### Modified Embodiments

The present invention is not limited to the above-described embodiments and can cover other various modifications.

For example, in the above-described embodiments, the present invention is applied to the magnetic memory device including TMR-type magnetoresistive effect elements. However, the present invention is also applicable to magnetic memory devices including GMR-type magnetoresistive effect elements. In this case, in place of the barrier layer 50, a conductive non-magnetic layer may be provided. The pinned magnetization layer 42 and the free magnetization layer 52 may be oppositely positioned the former on the latter.

In the above-described embodiments, the pinned magnetization layer 42 has the synthetic ferrimagnetic structure of CoFeB/Ru/CoFe to thereby decrease the leakage magnetic field from the pinned magnetization layer 42. However, the pinned magnetization layer may have a singly-layer structure of, e.g., CoFe.

In the above-described embodiment, the present invention is applied to a magnetic memory device comprising a memory cell including one select transistor and one magnetoresistive effect element. However, the structure of the memory cell is not limited to the above. The present invention is characterized mainly by the structure of the magnetoresistive effect element, and as far as a magnetic memory device includes the magnetoresistive effect element according to the present invention, the structures of the memory cells, the arrangement of the signal lines and other structures are not limited to the above.

What is claimed is:

1. A magnetic memory device comprising:
a magnetoresistive effect element including:
a first magnetic layer having a magnetization pinned in a first direction;
a non-magnetic layer formed on the first magnetic layer; and
a second magnetic layer formed on the non-magnetic layer, and having a first magnetic domain magnetized in the first direction and a second magnetic domain positioned adjacent to the first magnetic domain in the first direction and magnetized in a second direction opposite to the first direction; and
a write current applying circuit for flowing a write current to the second magnetic layer in the first direction or the second direction to shift a magnetic domain wall between the first magnetic domain and the second magnetic domain and control a magnetization direction of a part of the second magnetic layer, opposed to the first magnetic layer.

2. A magnetic memory device according to claim 1, wherein
the write current applying circuit flows the write current in the first direction to shift the magnetic domain wall in the second direction so that the second magnetic domain is positioned at a part where the second magnetic domain is opposed to the first magnetic layer, when a high-resistance state is written in the magnetoresistive effect element, and
the write current applying circuit flows the write current in the second direction to shift the magnetic domain wall in the first direction so that the first magnetic domain is positioned at a part where the first magnetic domain is opposed to the first magnetic layer, when a low-resistance state is written in the magnetoresistive effect element.

3. A magnetic memory device according to claim 1, further comprising:
a read current applying circuit for flowing a read current in a direction intersecting the first direction via the first magnetic layer, the non-magnetic layer and the second magnetic layer.

4. A magnetic memory device according to claim 1, wherein
the second magnetic layer has an elongated shape along the first direction and has notches for restricting a shift of the magnetic domain wall formed respectively near both ends.

5. A magnetic memory device according to claim 1, wherein
the first magnetic layer has a length along the first direction shorter than the second magnetic layer and positioned at a center of the second magnetic layer.

6. A magnetic memory device according to claim 1, wherein
the non-magnetic layer is formed of an insulating material.

7. A method for driving a magnetic memory device for driving a magnetic memory device including a magnetoresistive effect element including: a first magnetic layer having a magnetization pinned in a first direction; a non-magnetic layer formed on the first magnetic layer; and a second magnetic layer formed on the non-magnetic layer, and having a first magnetic domain magnetized in the first direction and a second magnetic domain positioned adjacent to the first magnetic domain in the first direction and magnetized in a second direction opposite to the first direction,
a write current of the first direction or the second direction is flowed in the second magnetic layer to shift a magnetic domain wall between the first magnetic domain and the second magnetic domain and control a magnetization direction of a part of the second magnetic layer, opposed to the first magnetic layer.

8. A method for driving a magnetic memory device according to claim 7, wherein when a high-resistance state is written in the magnetoresistive effect element, the write current is flowed in the first direction to shift the magnetic domain wall in the second direction so that the second magnetic domain is positioned at a part where the second magnetic domain is opposed to the first magnetic layer; and
when a low-resistance state is written in the magnetoresistive effect element, the write current is flowed in the second direction to shift the magnetic domain wall in the first direction so that the first magnetic domain is positioned at a part where the first magnetic domain is opposed to the first magnetic layer.

9. A method for driving a magnetic memory device according to claim 7, wherein
a read current is flowed in a direction intersecting the first direction via the first magnetic layer, the non-magnetic layer and the second magnetic layer, and based on a value of an outputted voltage, memory information of the magnetoresistive effect element is judged.
